(19) United States
(12) Patent Application Publication
(10) Pub. No.: US 2019/0067260 A1
(43) Pub. Date: Feb. 28, 2019

(54) SEMICONDUCTOR DEVICE AND METHOD FOR MANUFACTURING THE SAME

(71) Applicant: SUMITOMO ELECTRIC INDUSTRIES, LTD., Osaka (JP)

(72) Inventors: Koichi KOYAMA, Yokohama-shi (JP); Akira FURUYA, Yokohama-shi (JP)

(73) Assignee: SUMITOMO ELECTRIC INDUSTRIES, LTD., Osaka (JP)

(21) Appl. No.: 16/103,507

(22) Filed: Aug. 14, 2018

(30) Foreign Application Priority Data
Aug. 30, 2017 (JP) 2017-166158

(51) Int. Cl. H01L 25/16; H01L 23/00; H01L 23/498; H01L 23/15; H01L 25/00

(52) U.S. Cl. CPC H01L 25/167; H01L 24/48; H01L 23/49822; H01L 23/15; H01L 2224/81815; H01L 25/50; H01L 2224/48227; H01L 2224/85815; H01L 23/49811

(57) ABSTRACT

A semiconductor device includes: an interposer mounted on an upper surface of a printed board; a first semiconductor element mounted on an upper surface of the interposer; a second semiconductor element mounted on the upper surface of the printed board and performing conversion between an optical signal and an electrical signal; and a bonding wire connecting a first pad and a second pad, the first pad being provided on the upper surface of the interposer, the second pad being provided on an upper surface of the second semiconductor element, the first semiconductor element lowers a speed of an electrical signal input from the second semiconductor element and outputs the electrical signal to the printed board, and increases a speed of an electrical signal and outputs the electrical signal to the second semiconductor element via the interposer and the bonding wire.

### CROSS-REFERENCE TO RELATED APPLICATION

This application is based upon and claims the benefit of priority of the prior Japanese Patent Application No. 2017-166158, filed on Aug. 30, 2017, the entire contents of which are incorporated herein by reference.

### BACKGROUND

### (i) Technical Field

The present invention relates to a semiconductor device and a method of manufacturing the semiconductor device.

### (ii) Related Art

There are known technologies for mounting electronic components on a printed board (see Japanese Patent Application Laid-Open No. 2008-91522, for example).

### SUMMARY

Electronic components such as semiconductor chips are mounted on a printed board, and electrical connecting is performed with bonding wires. If the bonding wires are long, electrical signals might be degraded by the influence of the inductance of the bonding wires. Particularly, in a case where the electrical signals flowing in the bonding wires are high-speed electrical signals, there is a possibility that the electrical signals are severely degraded.

In view of the above, the present invention aims to provide a semiconductor device capable of preventing degradation of high-speed electrical signals, and a method of manufacturing the semiconductor device.

According to an aspect of the present invention, there is provided a semiconductor device including: a printed board; an interposer mounted on an upper surface of the printed board; a first semiconductor element mounted on an upper surface of the interposer; a second semiconductor element that is mounted on the upper surface of the printed board, is adjacent to the interposer, and performs conversion between an optical signal and an electrical signal; and a bonding wire that connects a first pad and a second pad, the first pad being provided on the upper surface of the interposer, the second pad being provided on an upper surface of the second semiconductor element, the first semiconductor element lowers a speed of an electrical signal input from the second semiconductor element via the bonding wire and the interposer and outputs the electrical signal to the printed board, and increases a speed of an electrical signal input from the printed board and outputs the electrical signal to the second semiconductor element via the interposer and the bonding wire.

According to another aspect of the present invention, there is provided a method of manufacturing a semiconductor device, comprising: the step of mounting a first semiconductor element on an upper surface of an interposer; the step of mounting the interposer on an upper surface of a printed board with a solder ball; the step of disposing a second semiconductor element on the upper surface of the printed substrate with a conductive paste, the second semiconductor element being adjacent to the interposer; and the step of electrically connecting a first pad to a second pad with a bonding wire, the first pad being provided on the upper surface of the interposer, the second pad being provided on an upper surface of the second semiconductor element.

### BRIEF DESCRIPTION OF THE DRAWINGS

FIG. 1A is a cross-sectional view of an example of a semiconductor device according to a first embodiment;

FIG. 1B is a plan view of the example of the semiconductor device;

FIG. 1C is a cross-sectional view of an example of a printed board;

FIG. 1D is a cross-sectional view of an example of an interposer;

FIG. 2 is an enlarged view of pads;

FIG. 3A is a cross-sectional view showing an example method of manufacturing the semiconductor device;

FIG. 3B is a plan view showing the example method of manufacturing the semiconductor device;

FIG. 4A is a cross-sectional view showing the example method of manufacturing the semiconductor device;

FIG. 4B is a plan view showing the example method of manufacturing the semiconductor device;

FIG. 5A is a cross-sectional view showing the example method of manufacturing the semiconductor device;

FIG. 5B is a plan view showing the example method of manufacturing the semiconductor device;

FIG. 6A is a cross-sectional view showing the example method of manufacturing the semiconductor device;

FIG. 6B is a plan view showing the example method of manufacturing the semiconductor device;

FIG. 7A is a cross-sectional view showing the example method of manufacturing the semiconductor device;

FIG. 7B is a plan view showing the example method of manufacturing the semiconductor device;

FIG. 8A is a cross-sectional view showing an example of a semiconductor device according to a comparative example;

FIG. 8B is a plan view showing the example of the semiconductor device; and

FIG. 9 is a cross-sectional view of an example of an interposer.

### DETAILED DESCRIPTION

[Description of Embodiments of the Present Invention]

First, the contents of modes of the present invention are listed below.

A mode of the present invention is 1) a semiconductor device that includes: a printed board; an interposer mounted on the upper surface of the printed board; a first semiconductor element mounted on the upper surface of the interposer; a second semiconductor element that is mounted on the upper surface of the printed board, is adjacent to the interposer, and performs conversion between an optical signal and an electrical signal; and a bonding wire that connects a first pad and a second pad, the first pad being provided on the upper surface of the interposer, the second pad being provided on the upper surface of the second semiconductor element. In this semiconductor device, the first semiconductor element lowers the speed of an electrical signal input from the second semiconductor element via the bonding wire and the interposer and outputs the electrical signal to the printed board, and increases the speed of an electrical signal input from the printed board and outputs the electrical signal to the second semiconductor element via the interposer and the bonding wire. With this structure, the distance between the interposer and the second semiconductor element becomes shorter, and accordingly, the bonding wire becomes shorter. As a result, the inductance of the bonding wire becomes lower, and thus, degradation of high-speed electrical signals is prevented.

2) The first pad may be provided at the edge of the upper surface of the interposer on the side of the second semiconductor element, and the second pad may be provided at the edge of the upper surface of the second semiconductor element on the side of the interposer. With this structure, the distance between the first pad and the second pad becomes shorter. Accordingly, the bonding wire becomes shorter, and thus, degradation of high-speed electrical signals is prevented.

3) The upper surface of the first pad of the interposer and the upper surface of the second pad of the second semiconductor element may be located at the same height, with the printed board being the reference. With this structure, there is no need to extend the bonding wire in the thickness direction, and accordingly, the bonding wire becomes shorter. Thus, degradation of high-speed electrical signals is prevented.

4) A wiring line that electrically connects the printed board to the first semiconductor element and extends in the thickness direction of the interposer may be provided in the interposer, and the first semiconductor element may lower the speed of an electrical signal input from the second semiconductor element and output the electrical signal to the printed board through the wiring line, and increase the speed of an electrical signal input from the printed board through the wiring line and output the electrical signal to the second semiconductor element. With this structure, the high-speed electrical signal path has fewer curves, and inductance becomes lower. Thus, degradation of high-speed electrical signals is prevented.

5) The length of the bonding wire may be equal to or smaller than 0.5 mm. With this, degradation of high-speed electrical signals is prevented.

6) The interposer and the second semiconductor element may be separated from each other, and the distance between the interposer and the second semiconductor element may be equal to or greater than 10 μm, and equal to or smaller than 20 μm. With this structure the bonding wire becomes shorter, and thus, degradation of high-speed electrical signals is prevented.

7) The interposer may be formed with a ceramic. With this, the relative dielectric constant of the interposer becomes lower, and dielectric loss of high-speed electrical signals can be prevented.

8) The interposer may be mounted on the upper surface of the printed board with a solder ball, and the second semiconductor element may be mounted on the upper surface of the printed board with a silver paste. The height can be adjusted between the first pad of the interposer and the second pad of the second semiconductor element. Thus, the bonding wire becomes shorter, and degradation of high-speed electrical signals is prevented.

9) A method of manufacturing a semiconductor device includes: the step of mounting a first semiconductor element on an upper surface of an interposer; the step of mounting the interposer on an upper surface of a printed board with a solder ball; the step of disposing a second semiconductor element on the upper surface of the printed substrate with a conductive paste, the second semiconductor element being adjacent to the interposer; and the step of electrically connecting a first pad to a second pad with a bonding wire, the first pad being provided on the upper surface of the interposer, the second pad being provided on an upper surface of the second semiconductor element. With this structure, the distance between the interposer and the second semiconductor element becomes shorter, and accordingly, the bonding wire becomes shorter. As a result, the inductance of the bonding wire becomes lower, and thus, degradation of high-speed electrical signals is prevented.

10) The step of mounting the interposer may include a solder reflow process, and, after the step of mounting the interposer, the second semiconductor element maybe disposed with the conductive paste at a lower temperature than the temperature of the solder reflow process in the step of disposing the second semiconductor element. When the conductive paste is used, the solder ball does not melt. Accordingly, the position of the interposer is prevented from shifting. Thus, an increase in the distance between the interposer and the second semiconductor element is prevented.

[Detailed Description of an Embodiment of the Present Invention]

The following is a description of specific examples of a semiconductor device and a method of manufacturing the semiconductor device according to an embodiment of the present invention, with reference to the drawings. It should be noted that the present invention is not limited to these examples but is indicated by the claims, and it is intended that all changes within the meanings and the scopes of the claims and the equivalents thereof are included therein.

### First Embodiment

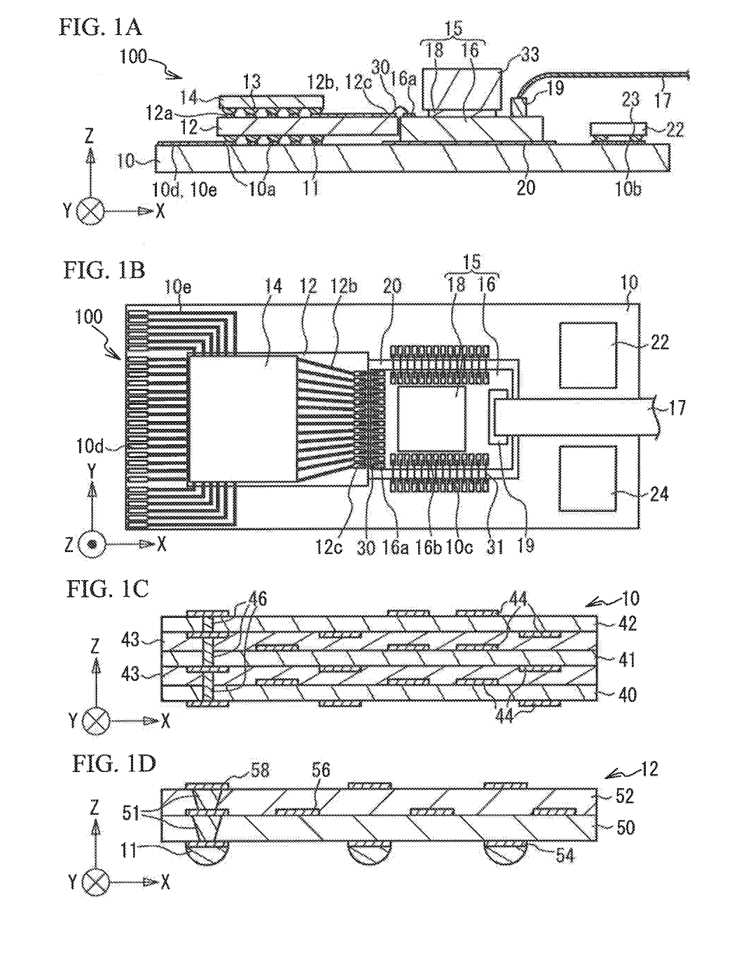

FIG. 1A is a cross-sectional view of an example of a semiconductor device 100 according to a first embodiment. FIG. 1B is a plan view of the example of the semiconductor device 100. The X-direction is the direction in which an interposer 12 and a semiconductor chip 16 are aligned. The Y-direction is the direction in which semiconductor components 22 and 24 are aligned. The Z-direction is the direction perpendicular to the X- and Y-directions.

As shown in FIGS. 1A and 1B, the semiconductor device 100 includes a printed board 10, an interposer 12, semiconductor elements 14 and 15, the semiconductor components 22 and 24, and a heat release block 33. The semiconductor element 15 includes semiconductor chips 16 and 18.

The interposer 12, the semiconductor chip 18, and the semiconductor components 22 and 24 are surface-mounted on the upper surface of the printed board 10. The semiconductor element 14 is surface-mounted on the upper surface of the interposer 12. The bare semiconductor chip 18 is installed on the upper surface of the semiconductor chip 16 by flip-chip mounting.

(Printed Board)

FIG. 1C is a cross-sectional view of an example of the printed board 10. As shown in FIG. 1C, the printed board 10 is a multi-layer substrate formed by bonding substrates 40 through 42 with prepregs 43. The substrates 40 through 42 and the prepregs 43 are formed with glass epoxy resin. Conductor layers 44 are disposed between the substrate 40 and the substrate 41, and between the substrate 41 and the substrate 42. The conductor layers 44 are electrically connected to one another with a via wiring line 46 (a through via) that penetrates through the printed board 10 in the thickness direction. The thickness of the printed board 10 is 2 mm, for example. As shown in FIG. 1A, pads 10a through 10d and a wiring pattern 10e are provided on the upper surface. The conductor layers 44 on the upper surface of the printed board 10 include the pads 10a through 10d and the wiring pattern 10e. The printed board 10 extends along the X-Y plane. The length of the printed board 10 in the X-direction is 45 mm, for example, and the length in the Y-direction is 15 mm, for example.

(Interposer)

FIG. 1D is a cross-sectional view of an example of the interposer 12. The interposer 12 is a multi-layered substrate that is formed with a ceramic such as alumina (Al₂O₃), and has a buildup structure. Insulating layers 50 and 52 are formed with a ceramic, and are bonded to each other. Conductor layers 54 are provided on the lower surface of the insulating layer 50, conductor layers 56 are provided between the insulating layers 50 and 52, and conductor layers 58 are provided on the upper surface of the insulating layer 52. The conductor layers are connected to one another with a via wiring line 51 that penetrates through the interposer 12 in the thickness direction (Z-direction). The via wiring line 51 is a stack via, for example. The via wiring line 51 may be perpendicular to the X-Y plane, or may be tilted with respect to the X-Y plane.

The conductor layers 54 are electrically connected to the pads 10a of the printed board 10 with solder balls 11 provided on the lower surface. The conductor layers 58 include pads 12a and 12c and a wiring pattern 12b shown in FIG. 1A. The thickness of the interposer 12 is 700 μm, for example, and the height of the solder balls 11 is 75 μm, for example. Accordingly, the height from the upper surface of the printed board 10 to the upper surface of the mounted interposer 12 is 775 μm, for example.

As shown in FIGS. 1A and 1B, the end face of the interposer 12 (the side surface on the +X-side) protrudes from the end face of the semiconductor element 14, and faces the end face of the semiconductor chip 16 (the side surface on the −X-side) but keeps a distance therefrom. The pads 12c (first pads) of the interposer 12 are located at the edge of the upper surface on the side of the semiconductor chip 16. The wiring pattern 12b electrically connects the pads 12a to the pads 12c.

(Semiconductor Element 14)

In the semiconductor element 14 (a first semiconductor element), an integrated circuit (IC) such as a SERializer/DESerializer-IC (SERDES-IC) is housed in a package having a ball grid array (BGA). The semiconductor element 14 is electrically connected to the pads 12a of the interposer 12. The semiconductor element 14 integrates low-speed electrical signals into a high-speed electrical signal, and divides a high-speed electrical signal into low-speed electrical signals. Here, “high-speed” means having a high modulation baud rate, and “low-speed” means having a low modulation baud rate.

(Semiconductor Element 15)

The semiconductor element 15 is a photonics integrated circuit (PIC) or the like, for example, and includes the semiconductor chips 16 and 18. The semiconductor element 15 converts an electrical signal input from the interposer 12 into a modulated optical signal, and outputs the modulated optical signal to an optical fiber 17. The semiconductor element 15 also converts an optical signal input from the optical fiber 17 into an electrical signal, and outputs the electrical signal to the interposer 12.

The semiconductor chip 16 (a second semiconductor element) is mounted on the upper surface of the printed board 10 with silver (Ag) paste 20 of several μm in thickness, for example. The semiconductor chip 16 is a photo IC (PIC) that includes a silicon-on-insulator (SOI) substrate, Mach-Zehnder modulators provided on the SOI substrate, and a germanium (Ge) photodetector (PD). The semiconductor chip 16 is 0.8 mm thickness, for example. A port (a grating coupler) for inputting/outputting optical signals is provided on the upper surface of the semiconductor chip 16, and is connected to a holder 19. The semiconductor chip 16 converts an input optical signal into an electrical signal, and converts an input electrical signal into an optical signal.

The upper surface of the semiconductor chip 16 is located at the same height as the upper surface of the interposer 12. Pads 16a and 16b are provided on the upper surface of the semiconductor chip 16. The pads 16a (seconds pads) are located at the edge of the upper surface on the side of the interposer 12. The pads 16a are electrically connected to the pads 12c of the interposer 12 with bonding wires 30 of 0.5 mm or shorter, for example. The pads 16b are electrically connected to the pads 10c of the printed board 10 with bonding wires 31.

The semiconductor chip 18 is mounted on the upper surface of the semiconductor chip 16 by flip-chip mounting, and is electrically connected to the semiconductor chip 16. The semiconductor chip 18 is an electronic integrated circuit (EIC) that includes a driver for the Mach-Zehnder modulators, and a transimpedance amplifier (TIA). The driver amplifies a high-speed electrical signal, and inputs the amplified electrical signal as a drive signal to the semiconductor chip 16, to drive the modulators in the semiconductor chip 16. The TIA amplifies a signal of the PD. The heat release block 33 is mounted on the upper surface of the semiconductor chip 18. The heat generated in the semiconductor element 15 is released through the heat release block 33.

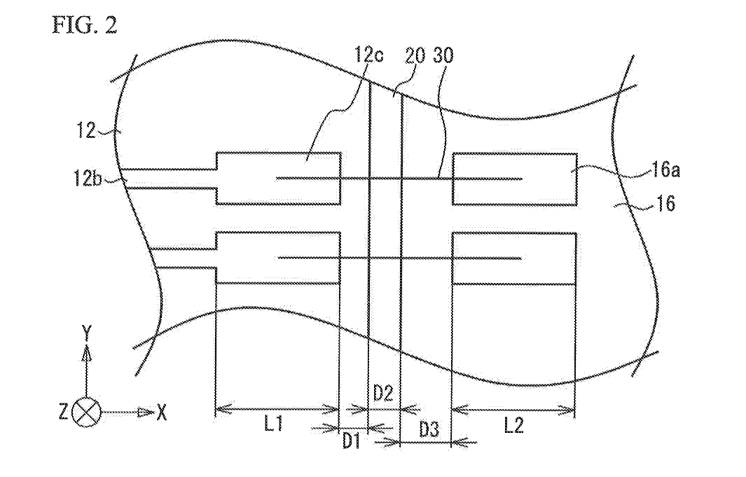

FIG. 2 is an enlarged view of pads 12c and pads 16a. As shown in FIG. 2, the pads 12c and the pads 16a each have a rectangular shape, for example. The length L1 of each side of the pads 12c in the X-direction and the length L2 of each side of the pads 16a are both 75 μm. The distance D1 from the edge of each pad 12c to the end face of the interposer 12 is determined by the processing accuracy of the interposer 12, and is 50±50 μm, for example. As the interposer 12 is formed by dicing, for example, the processing accuracy becomes higher, and the tolerance of the distance D1 becomes approximately ±50 μm. The distance between two bonding wires 30 adjacent to each other in the Y-direction is 150 μm, for example. The distance D3 from the edge of each pad 16a to the end face of the semiconductor chip 16 is 100±50 μm, for example.

In a high-temperature environment, the interposer 12 and the semiconductor chip 16 thermally expand, and the end faces of the two components come into contact with each other. As a result, stress might be generated. To prevent such contact, the end face of the interposer 12 and the end face of the semiconductor chip 16 are separated from each other, and the distance D2 between these end faces is 10 to 20 μm, for example. Further, the end face of the interposer 12 and the end face of the semiconductor chip 16 are parallel to each other in the Y-direction.

One end of each bonding wire 30 is connected to a central portion of the corresponding pad 16a, and the other end is connected to a central portion of the corresponding pad 12c. The maximum length of the bonding wires 30 is calculated in the following manner.

The distance (L1/2+D1) from the center of the pad 12c to the end face of the interposer 12+the absolute value (50 μm) of the tolerance of D1+the distance D2+the distance (D3+L2/2) from the end face of the semiconductor chip 16 to the center of the pad 16a+the absolute value (50 μm) of the tolerance of D3

The length of the bonding wires 30 is 500 μm (0.5 mm) or shorter, for example, and the maximum length thereof is 345 μm, for example. The diameter of the bonding wires 30 is 25 μm, for example.

The pads, the wiring patterns, and the via wiring lines are formed with a metal such as aluminum (Al) or copper (Cu), for example. The bonding wires are formed with a metal such as gold (Au) or Al, for example.

(Optical Fiber)

The optical fiber 17 extends in an upward direction and a horizontal direction (the Z- and X-directions), and is inserted into and supported by the holder 19. The optical fiber 17 is connected to a port of the semiconductor chip 16, and is optically coupled to the semiconductor chip 16. An optical signal is output from the semiconductor chip 16 to an external device through the optical fiber 17. An optical signal is also input to the semiconductor chip 16 through the optical fiber 17. The optical fiber 17 is designed in accordance with the number of the channels for optical inputs or optical outputs of the semiconductor chip 16. The optical fiber 17 may be a single fiber, or may be an array of optical fibers.

The semiconductor components 22 and 24 mounted on the upper surface of the printed board 10 are components formed by packaging an IC for a power supply regulator or a CPU for controlling circuits, for example. Chip components such as resistors and capacitors may be mounted on the printed board 10.

For example, four pairs of (or eight) electrical signals at 25 Gbaud are input from an external electronic device to the pads 10d of the printed board 10, and are further input to the semiconductor element 14 via the interposer 12. The semiconductor element 14 increases the speed of the eight 25-Gbaud electrical signals to obtain four 50-Gbaud electrical signals, and then outputs the four electrical signals to the wiring pattern 12b of the interposer 12. The sped-up electrical signals are then input to the pads 16a of the semiconductor chip 16 via the wiring pattern 12b and the pads 12c of the interposer 12 and the bonding wires 30. The semiconductor chip 16, which has received the electrical signals, modulates continuous light input from the optical fiber 17 into a 50G Gbaud optical signal, and outputs the optical signal to the optical fiber 17.

For example, a 50-Gbaud optical signal is input from the optical fiber 17 to the semiconductor chip 16. The semiconductor chip 16 converts the optical signal into 50-Gbaud electrical signals, and outputs the electrical signals to the pads 12c of the interposer 12 via the pads 16a and the bonding wires 30. The four 50-Gbaud electrical signals are input to the semiconductor element 14 via the interposer 12. The semiconductor element 14 lowers the speed of the electrical signals to 25 Gbaud, and divides the four electrical signals into eight. The semiconductor element 14 then outputs the eight electrical signals to the pads 10a of the printed board 10 via the interposer 12 and the solder balls 11.

In optical communication, high-speed electrical signals at 50 Gbaud or higher are used in some cases. It should be noted that the semiconductor element 14 may convert ten 10-Gbaud electrical signals into four 25-Gbaud electrical signals, for example. A 10-Gbaud signal is a signal having 10G signal frames per second, and is equivalent to a signal speed of 10 Gbps in the NRZ format, and a signal speed of 20 Gbps in the PAM4 (4-value pulse-amplitude modulation) format.

(Method of Manufacturing the Semiconductor Device)

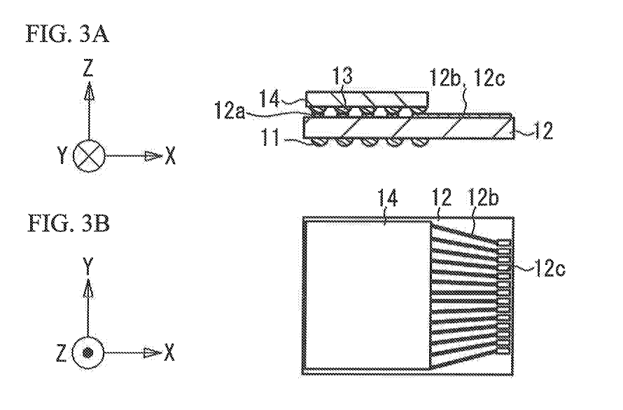

FIGS. 3A, 4A, 5A, 6A, and 7A are cross-sectional views showing an example method of manufacturing the semiconductor device 100. FIGS. 3B, 4B, 5B, 6B, and 7B are plan views showing the example method of manufacturing the semiconductor device 100.

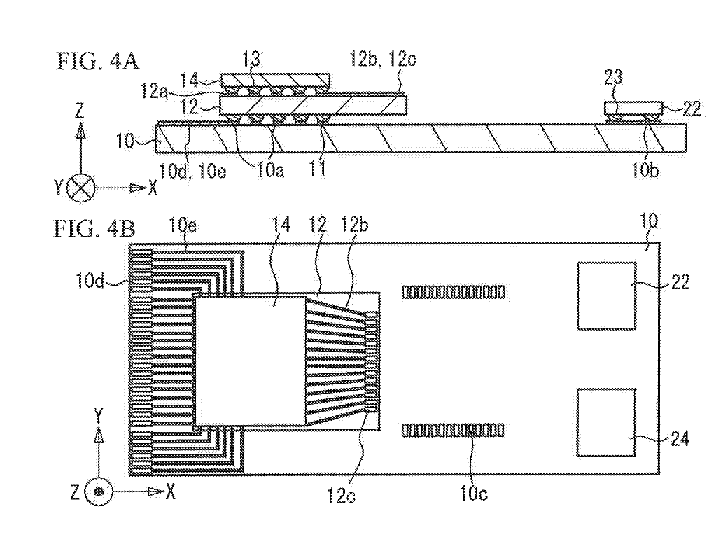

As shown in FIGS. 3A and 3B, the semiconductor element 14 is surface-mounted on the upper surface of the interposer 12 with solder balls 13 or the like. As shown in FIGS. 4A and 4B, a reflow process at 270 degrees C. is performed, for example, so that the interposer 12 and the semiconductor components 22 and 24 are surface-mounted on the upper surface of the printed board 10 with solder balls 11. After the reflow, the height of the solder balls 11 is 75 μm, for example, and the height from the upper surface of the printed board 10 to the upper surface of the interposer 12 is 775 μm, for example.

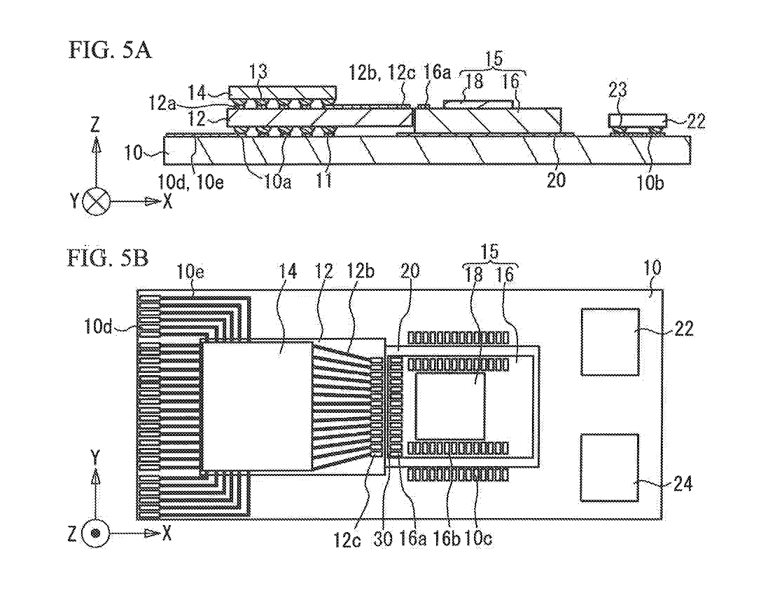

As shown in FIGS. 5A and 5B, the semiconductor chip 18 is mounted on the upper surface of the semiconductor chip 16 by flip-chip mounting. The semiconductor chip 18 is mounted before the semiconductor chip 16 is mounted on the printed board 10. The flip-chip mounting of the semiconductor chip 18 on the upper surface of the semiconductor chip 16 is performed via inter-chip connecting components such as copper pillars (not shown), for example. The semiconductor chip 16 is secured onto the upper surface of the printed board 10 with the Ag paste 20. Specifically, the semiconductor chip 16 is made to slide on the Ag paste 20, and thus, is positioned. The Ag paste 20 is then solidified, to secure the semiconductor chip 16. The temperature at the time of the solidification of the Ag paste 20 is lower than the temperature of the reflow of the solder balls. Accordingly, the solder balls 11 and 13 do not melt, and the interposer 12 and the semiconductor element 14 do not move.

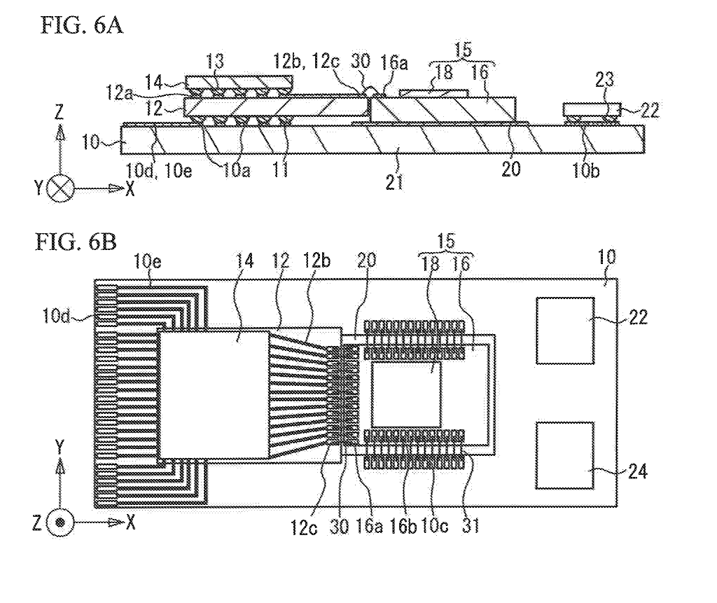

As shown in FIGS. 6A and 6B, wire bonding is performed. The bonding wires 30 electrically connect the pads 12c to the pads 16a. The bonding wires 31 electrically connect the pads 16b to the pads 10c. For example, wedge bonding is used for the bonding wires 30. For the bonding wires 31, it is possible to use either wedge bonding or ball bonding. The temperature of the wire bonding is lower than the temperature of the solder reflow, and thus, the solder balls 11 and 13 do not melt.

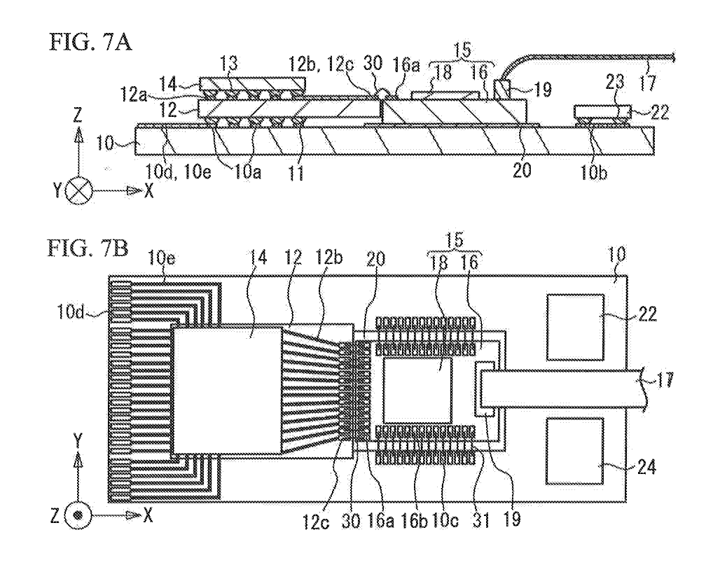

As shown in FIGS. 7A and 7B, the optical fiber 17 is connected to the semiconductor chip 16. The holder 19 to which the optical fiber 17 is attached is placed on the port of the semiconductor chip 16. Monitor light is input through the optical fiber 17, and the intensity of the electrical signals is measured with a probe in contact with the pads 10d of the printed board 10. The position of the holder 19 is then adjusted so that the intensity of the electrical signals is maximized. The optical adhesive is solidified with ultraviolet rays, so that the holder 19 is secured to the semiconductor chip 16. Further, the heat release block 33 shown in FIGS. 1A and 1B is mounted. Through the above process, the semiconductor device 100 is formed. The semiconductor device 100 may be housed in the housing of an optical transceiver, for example.

### COMPARATIVE EXAMPLE

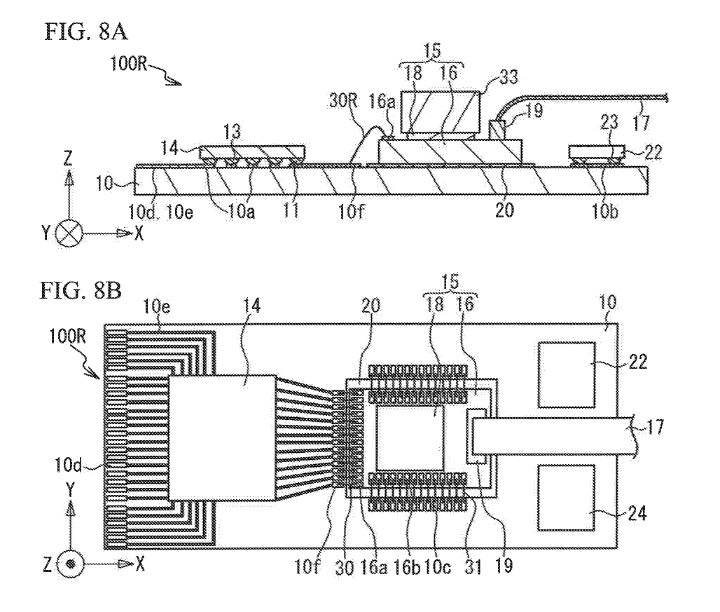

Next, a comparative example is described. FIG. 8A is a cross-sectional view of an example of a semiconductor device 100 R according to the comparative example. FIG. 8B is a plan view of the example of the semiconductor device 100R. The same components as those of the first embodiment will not be explained below.

As shown in FIGS. 8A and 8B, the semiconductor device 100R does not include the interposer 12. The semiconductor element 14 is surface-mounted on the upper surface of the printed board 10. The pads 16a on the upper surface of the semiconductor chip 16 are connected to pads 10f on the upper surface of the printed board 10 with bonding wires 30R.

The bonding wires 30R extend from the pads 10f on the upper surface of the printed board 10 to the pads 16a. Therefore, the length of the bonding wires 30R is greater than the thickness of the semiconductor chip 16, and is approximately 1 to 1.5 mm in some cases, for example. Where the bonding wires 30R are long, inductance increases, and the waveforms of electrical signals are degraded. Particularly, high-speed electrical signals at 50 Gbaud or the like are likely to be affected by inductance. Therefore, in the comparative example, the waveforms of the high-speed electrical signals flowing in the bonding wires 30R are greatly degraded.

In the first embodiment, the interposer 12 and the semiconductor chip 16 are adjacent to each other on the upper surface of the printed board 10. Therefore, the bonding wires 30 that connect the pads 12c of the interposer 12 to the pads 16a of the semiconductor chip 16 can be made shorter. For example, the interposer 12 is made closer to the semiconductor chip 16 than the semiconductor element 14, so that the bonding wires 30 are made shorter. As a result, degradation and loss of the waveforms of the high-speed electrical signals flowing in the bonding wires 30 can be prevented.

As shown in FIG. 1B, the pads 12c are disposed along the edge (side) of the interposer 12 on the side of the semiconductor chip 16 (the +X-side). The pads 16a are disposed along the edge of the semiconductor chip 16 on the side of the interposer 12 (the −X-side). As the distance between the pads is shorter, the bonding wires 30 can be shorter. Thus, degradation and loss of the waveforms of electrical signals can be prevented.

As shown in FIG. 2, the interposer 12 and the semiconductor chip 16 are separated. To make the bonding wires 30 shorter, the distance D2 is preferably short, and is not shorter than 10 μm and not longer than 20 μm, for example. Even if the interposer 12 and the semiconductor chip 16 expand in a high-temperature environment, contact can be prevented. Thus, damage or the like due to stress can be prevented.

In the example shown in FIG. 8A, the bonding wires 30R extend in the Z-direction over a distance equal to or greater than the thickness of the semiconductor chip 16, and therefore, are long. As shown in FIG. 1A, in this embodiment, the upper surfaces of the pads 12c of the interposer 12 and the upper surfaces of the pads 16a of the semiconductor chip 16 are located at the same height, with the printed board 10 being the reference. The bonding wires 30 extend along the X-Y plane, and can be made effectively shorter. Particularly, by wedge bonding, it is possible to form bonding wires 30 that extend along the X-Y plane and are short in the Z-direction. The pads 12c and the pads 16a may be located in exactly the same plane, or may have a difference of 10 μm or smaller in height, for example.

The length of the bonding wires 30 is preferably not greater than 0.5 mm. With this, degradation and loss of the waveforms of high-speed electrical signals can be prevented. The length of the bonding wires 30 may be not greater than 1 mm, not greater than 0.8 mm, or not greater than 0.3 mm. The modulation rate of the electrical signals flowing in the bonding wires 30 is higher than the electrical signals to be supplied to the printed board 10, and is not lower than 25 Gbaud, not lower than 50 Gbaud, or not lower than 64 Gbaud, for example. It is also possible to determine the length of the bonding wires 30 in accordance with the modulation rate so that degradation of electrical signals can be prevented.

As shown in FIG. 1A, the interposer 12 is surface-mounted on the upper surface of the printed board 10 with the solder balls 11, and the semiconductor chip 16 is surface-mounted on the upper surface of the printed board 10 with the Ag paste 20. As the solder balls 11 are connected to the pads 10a, the interposer 12 and the printed board 10 can be electrically connected to each other. To prevent shifting and tilting of the position of the semiconductor chip 16, the thickness of the Ag paste 20 is preferably several μm.

The Ag paste 20 is thinner than the solder balls 11. Therefore, the semiconductor chip 16 is preferably thicker than the interposer 12. With this, the pads 12c and the pads 16a can have approximately the same heights. Particularly, the sum of the height of the solder balls 11 and the thickness of the interposer 12 is preferably equal to the sum of the thickness of the Ag paste 20 and the thickness of the semiconductor chip 16. The pads 12c and the pads 16a are located in the same plane, and the bonding wires 30 are short accordingly.

In the reflow, the solder balls 11 melt at 270 degrees C., for example, and is solidified by cooling. In mounting of the semiconductor chip 16, the Ag paste 20 is solidified at a lower temperature than the reflow temperature. Accordingly, the solder balls 11 do not melt even though the semiconductor chip 16 is mounted after the reflow process. Thus, shifting of the position of the interposer 12 is prevented, and an increase in the distance D2 is prevented. Further, wire bonding is preferably performed at a lower temperature than the melting point of the solder and the Ag paste 20. Thus, shifting of the positions of the interposer 12 and the semiconductor chip 16 can be prevented. It should be noted that it is possible to use an adhesive having a lower melting point than the solder, such as a conductive paste other than the Ag paste 20.

As shown in FIG. 1D, the interposer 12 is provided with the via wiring line 51 extending in the thickness direction. For example, a high-speed electrical signal at 50 Gbaud flows between the semiconductor element 14 and the semiconductor chip 16 (the wiring pattern 12b, the pads 12c and 16a, and the bonding wires 30), but does not flow in the printed board 10 and the via wiring line 51. The wiring pattern 12b, and the pads 12c and 16c are located in the same plane, for example, and the bonding wires 30 connect the pads 12c to the pads 16a. That is, the high-speed electrical signal path extends along the X-Y plane, is short in distance in the Z-direction, and has few sharp curves. Therefore, the inductance of the path is low, the thus, degradation and loss of high-speed electrical signals are prevented. For example, a low-speed electrical signal at 25 Gbaud is less degraded than a high-speed electrical signal, even when propagating a path curved at 90 degrees between the wiring pattern 10e and the via wiring line 51.

The interposer 12 is formed with a ceramic such as Al₂O₃, for example. A ceramic can be processed by dicing or the like with a higher accuracy than glass epoxy resin or the like, for example. Also, a ceramic hardly has burrs and sagging. Thus, the tolerance of the distance D1 shown in FIG. 2 can be 50 μm or less, for example. Accordingly, the interposer 12 and the semiconductor chip 16 can be made closer to each other, and the bonding wires 30 can be made shorter. Also, the flatness of the interposer 12 becomes higher, and thus, the semiconductor element 14 having a BGA structure can be surface-mounted in a stable manner.

The dielectric loss of a high-frequency signal is greater than that of a low-frequency signal. Therefore, the interposer 12 in which high-speed electrical signals propagate is preferably formed with a material having a low relative dielectric constant, such as a ceramic. Since a material having low dielectric loss, such as a ceramic, is expensive, the costs become much higher if the entire printed board 10 is formed with a ceramic. Therefore, the printed board 10 is formed with an inexpensive material such as glass epoxy resin, as shown in FIG. 1C, for example. Since electrical signals that propagates in the printed board 10 have a low speed, the dielectric loss is small. Further, the interposer 12 in which electrical signals with the highest frequency propagate is formed with a low-dielectric constant ceramic or the like. Since the interposer 12 is smaller than the printed board 10, a large increase in cost can be prevented with the use of a ceramic. Dielectric loss of high-frequency signals that propagates in the interposer 12 is also prevented.

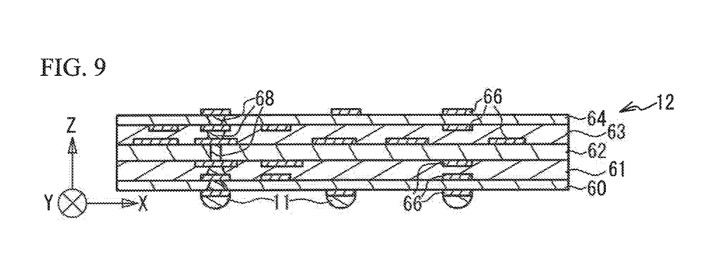

The interposer 12 may be formed with a material other than a ceramic. FIG. 9 is a cross-sectional view of an example of the interposer 12. The interposer 12 is a multi-layer substrate having a buildup structure in which insulating layers 60 through 64 of glass epoxy resin are stacked. Conductive layers 66 are provided on the upper surface, the lower surface, and between the insulating layers. Some of the conductive layers are connected to one another with a via wiring line 68. To achieve a high processing accuracy and prevent burrs, the insulating layers 60 through 64 are preferably thinner than the substrate 40 of the printed board 10 or the like. Particularly, the uppermost insulating layer 64 is preferably thin.

The interposer 12 may be formed by a method other than dicing. To increase accuracy, dicing is particularly preferable. In dicing, the materials are shaven off, and therefore, there is no need to take into account grinding undercut of the materials. Accordingly, dicing can achieve a higher accuracy than punching and routing. Thus, the tolerance of the distance D2 can be made smaller, and the bonding wires 30 can be made shorter. The thermal expansion coefficient of the interposer 12 may be somewhere between the printed board 10 and the semiconductor element 14. Thermal stress can be reduced.

What is claimed is:

1. A semiconductor device comprising:
a printed board;
an interposer mounted on an upper surface of the printed board;
a first semiconductor element mounted on an upper surface of the interposer;
a second semiconductor element that is mounted on the upper surface of the printed board, is adjacent to the interposer, and performs conversion between an optical signal and an electrical signal; and
a bonding wire that connects a first pad and a second pad, the first pad being provided on the upper surface of the interposer, the second pad being provided on an upper surface of the second semiconductor element,
wherein the first semiconductor element lowers a speed of an electrical signal input from the second semiconductor element via the bonding wire and the interposer and outputs the electrical signal to the printed board, and increases a speed of an electrical signal input from the printed board and outputs the electrical signal to the second semiconductor element via the interposer and the bonding wire.

2. The semiconductor device according to claim 1, wherein
the first pad is provided at an edge of the upper surface of the interposer on a side of the second semiconductor element, and
the second pad is provided at an edge of the upper surface of the second semiconductor element on a side of the interposer.

3. The semiconductor device according to claim 1, wherein an upper surface of the first pad of the interposer and an upper surface of the second pad of the second semiconductor element are located at the same height, with the printed board being a reference.

4. The semiconductor device according to claim 1, wherein
a wiring line that electrically connects the printed board to the first semiconductor element and extends in a thickness direction of the interposer is provided in the interposer, and
the first semiconductor element lowers a speed of an electrical signal input from the second semiconductor element and outputs the electrical signal to the printed board through the wiring line, and increases a speed of an electrical signal input from the printed board through the wiring line and outputs the electrical signal to the second semiconductor element.

5. The semiconductor device according to claim 1, wherein the bonding wire is not longer than 0.5 mm.

6. The semiconductor device according to claim 1, wherein
the interposer and the second semiconductor element are separated from each other, and
a distance between the interposer and the second semiconductor element is not shorter than 10 μm and not longer than 20 μm.

7. The semiconductor device according to claim 1, wherein the interposer is formed with a ceramic.

8. The semiconductor device according to claim 1, wherein
the interposer is mounted on the upper surface of the printed board with a solder ball, and
the second semiconductor element is mounted on the upper surface of the printed board with a silver paste.

9. A method of manufacturing a semiconductor device, comprising:
a step of mounting a first semiconductor element on an upper surface of an interposer;
a step of mounting the interposer on an upper surface of a printed board with a solder ball;
a step of disposing a second semiconductor element on the upper surface of the printed substrate with a conductive paste, the second semiconductor element being adjacent to the interposer; and
a step of electrically connecting a first pad to a second pad with a bonding wire, the first pad being provided on the upper surface of the interposer, the second pad being provided on an upper surface of the second semiconductor element.

10. The method of manufacturing a semiconductor device according to claim 9, wherein
the step of mounting the interposer includes a solder reflow process, and
after the step of mounting the interposer, the second semiconductor element is disposed with the conductive paste at a lower temperature than a temperature of the solder reflow process in the step of disposing the second semiconductor element.
